(19) United States
(12) Patent Application Publication
(10) Pub. No.: US 2024/0101865 A1
(43) Pub. Date: Mar. 28, 2024

(54) TUNGSTEN CMP COMPOSITION INCLUDING A SULFUR CONTAINING ANIONIC SURFACTANT

(71) Applicant: CMC Materials LLC, Aurora, IL (US)

(72) Inventors: Na ZHANG, Naperville, IL (US); Bosky SONI, Aurora, IL (US)

(21) Appl. No.: 18/370,021

(22) Filed: Sep. 19, 2023

Related U.S. Application Data
(60) Provisional application No. 63/409,079, filed on Sep. 22, 2022.

(51) Int. Cl. C09G 1/02

(52) U.S. Cl. CPC C09G 1/02

(57) ABSTRACT

A chemical mechanical polishing composition for tungsten CMP consists of, consists essentially of, or comprises a liquid carrier, cationic abrasive particles dispersed therein, an iron-containing accelerator, a tungsten etch inhibitor, a sulfur containing anionic surfactant, and has a pH of less than about 5.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for polishing various metal (such as tungsten) and non-metal (such as silicon oxide) layers on a semiconductor substrate may include abrasive particles suspended in an aqueous solution and various chemical additives such as oxidizers, chelating agents, catalysts, topography control agents, buffers, and the like.

In a conventional CMP operation, the substrate (wafer) to be polished is mounted on a carrier which is in turn mounted on a carrier assembly and positioned in contact with a polishing pad in a CMP polishing tool. The carrier assembly provides a controlled pressure to the substrate against the polishing pad. The substrate and pad are moved relative to one another by an external driving force. The relative motion of the substrate and pad abrades and removes a portion of the material (e.g., tungsten) from the surface of the substrate, thereby polishing the substrate. The polishing of the substrate by the relative movement of the pad and the substrate may be further aided by the chemical activity of the polishing composition and/or the mechanical activity of an abrasive suspended in the polishing composition.

As is well known, there is a strong demand for continued miniaturization in the semiconductor industry. This miniaturization leads to reduced device feature sizes and more stringent planarization requirements in commercial CMP processes. There is a need in the industry for CMP compositions (e.g., tungsten CMP compositions) that provide for improved planarity without sacrificing throughput and increasing costs.

### BRIEF SUMMARY OF THE INVENTION

A chemical mechanical polishing composition is disclosed for use in tungsten CMP operations. The composition consists of, consists essentially of, or comprises a liquid carrier, cationic abrasive particles dispersed in the liquid carrier, an iron-containing accelerator, a tungsten etch inhibitor, a sulfur containing anionic surfactant. The composition has a pH of less than about 5.

### DETAILED DESCRIPTION OF THE INVENTION

Chemical mechanical polishing compositions are disclosed for polishing tungsten. In one embodiment, the composition includes liquid carrier and cationic abrasive particles (such as cationic colloidal silica particles) dispersed therein. The polishing composition may further include an iron-containing accelerator, a tungsten etch inhibitor, and a sulfur containing anionic surfactant. Methods of using the disclosed compositions for polishing tungsten containing substrates are also disclosed.

It will be appreciated that the disclosed CMP compositions may be advantageously utilized for bulk tungsten removal CMP operations (which are sometimes referred to in the art as first step tungsten CMP operations). Bulk removal operations generally require higher tungsten removal rates and low tungsten etch rates. The disclosed CMP compositions may also be advantageously utilized for single step tungsten CMP operations. The disclosed polishing compositions have been found to advantageously provide a high tungsten removal rate as well as improved planarity and reduced patterned oxide loss. The compositions may therefore provide for improved topography control, for example, improved erosion and dishing on device wafers.

The disclosed polishing composition generally contains abrasive particles suspended in a liquid carrier. The liquid carrier is used to facilitate the application of the abrasive particles and chemical additives to the surface of the substrate to be polished (e.g., planarized). The liquid carrier may include any suitable carrier (e.g., a solvent) including lower alcohols (e.g., methanol, ethanol, etc.), ethers (e.g., dioxane, tetrahydrofuran, etc.), water, and mixtures thereof. The liquid carrier preferably consists of, or consists essentially of, deionized water.

The abrasive particles may include substantially any suitable cationic abrasive particles, for example, including alpha alumina particles, silica particles, and/or aluminum doped silica particles. By cationic it is meant that the abrasive particles are positively charged at the pH of the polishing composition. In preferred embodiments, the abrasive particles may include cationic silica particles such as cationic fumed silica particles or cationic colloidal silica particles. Cationic colloidal silica particles are most preferred. As used herein the term colloidal silica particles refers to silica particles that are prepared via a wet process rather than the pyrogenic or flame hydrolysis process used to produce fumed silica. It will be appreciated that colloidal silica particles and fumed silica particles are generally structurally different particles. Colloidal silica may be precipitated or condensation-polymerized silica, which may be prepared using any method known to those of ordinary skill in the art, such as by the sol gel method or by silicate ion-exchange. Condensation-polymerized silica particles are often prepared by condensing Si(OH)₄ to form substantially spherical particles. Preferred embodiments include colloidal silica particles.

As known to those of ordinary skill in the art, colloidal silica particles may be aggregated or non-aggregated. Non-aggregated particles are individually discrete particles that may be spherical or nearly spherical in shape, but can have other shapes as well (such as generally elliptical, square, or rectangular cross-sections). Aggregated particles are particles in which multiple discrete particles are clustered or bonded together to form aggregates having generally irregular shapes. Aggregated colloidal silica particles are disclosed, for example, in commonly assigned U.S. Pat. No. 9,309,442.

The charge on silica particles is commonly referred to in the art as the zeta potential (or the electrokinetic potential). As known to those of ordinary skill in the art, the zeta potential of a particle refers to the electrical potential difference between the electrical charge of the ions surrounding the particle and the electrical charge of the bulk solution of the polishing composition (e.g., the liquid carrier and any other components dissolved therein). The zeta potential may be obtained using commercially available instrumentation such as the Zetasizer available from Malvern Instruments, the ZetaPlus Zeta Potential Analyzer available from Brookhaven Instruments, and/or an electro-acoustic spectrometer available from Dispersion Technologies, Inc.

In example embodiments, the polishing composition may include cationic silica particles having a positive charge in the polishing composition of about 10 mV or more (e.g., about 15 mV or more, about 20 mV or more, or about 25 mV or more). The cationic silica particles may have a positive charge in the polishing composition of about 60 mV or less (e.g., about 55 mV or less or about 50 mV or less). Accordingly, it will be understood that the cationic silica particles may have a positive charge in the polishing composition in a range bounded by any one of the aforementioned endpoints, for example, in a range from about 10 mV to about 60 mV (e.g., about 15 mV to about 60 mV, about 20 mV to about 50 mV, or about 25 mV to about 50 mV).

While the disclosed embodiments are not limited in this regard, the cationic silica particles may advantageously have a permanent positive charge. By permanent positive charge it is meant that the positive charge on the silica particles is not readily reversible, for example, via flushing, dilution, filtration, and the like. A permanent positive charge may be the result, for example, of covalently bonding a cationic compound with the colloidal silica (e.g., with an external surface of the particles). A permanent positive charge is in contrast to a reversible positive charge that may be the result, for example, of an electrostatic interaction between a cationic compound and the silica. Notwithstanding, as used herein, a permanent positive charge of at least 10 mV means that the zeta potential of the silica particles remains above 10 mV after the three-step ultrafiltration test described in further detail in commonly assigned U.S. Pat. No. 9,238,754.

Cationic silica particles having a permanent positive charge in the polishing composition may be obtained, for example, via treating the particles with at least one aminosilane compound as disclosed in commonly assigned U.S. Pat. Nos. 7,994,057 and 9,028,572. Alternatively, silica particles having a permanent positive charge in the polishing composition may be obtained by incorporating a chemical species, such as an aminosilane compound, internally in the silica particles as disclosed in in commonly assigned U.S. Pat. No. 9,422,456.

The cationic silica particles may alternatively have a non-permanent positive charge imparted thereto, for example, via contact with a cation-containing component (i.e., a positively charged species) in the liquid carrier. A non-permanent positive charge may be achieved, for example, via treating the particles with at least one cation-containing component, for example, selected from ammonium salts (preferably quaternary amine compounds), phosphonium salts, sulfonium salts, imidazolium salts, and pyridinium salts.

The abrasive particles in the disclosed embodiments may have substantially any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, Louisiana) or the Zetasizer® available from Malvern Instruments®. The abrasive particles may have an average particle size of about 10 nm or more (e.g., about 20 nm or more, about 40 nm or more, or about 50 nm or more). The abrasive particles may have an average particle size of about 200 nm or less (e.g., about 180 nm or less, about 160 nm or less, or about 150 nm or less). Accordingly, the colloidal silica particles may have an average particle size in a range from about 5 nm to about 200 nm (e.g., from about 20 nm to about 180 nm, from about 40 nm to about 160 nm, or from about 50 nm to about 150 nm).

The polishing composition may include substantially any suitable amount of the above-described abrasive particles, but preferably includes a low concentration of abrasive particles at point of use to reduce costs. It will be understood that compositions having a low concentration of abrasive particles at point of use may also be more highly concentratable thereby potentially further reducing costs. For example, the polishing composition may include about 0.01 wt. % or more abrasive particles at point of use (e.g., about 0.02 wt. % or more, about 0.03 wt. % or more, or about 0.05 wt. % or more). The amount of abrasive particles in the polishing composition may include about 10 wt. % or less at point of use (e.g., about 2 wt. % or less, about 1 wt. % or less, about 0.5 wt. % or less, about 0.3 wt. % or less, or even about 0.2 wt. % or less). Accordingly, it will be understood that the amount of abrasive particles may be in a range bounded by any two of the aforementioned endpoints, for example, in a range from about 0.01 wt. % to about 10 wt. % at point of use (e.g., from about 0.01 wt. % to about 2 wt. %, from about 0.02 wt. % to about 1 wt. %, from about 0.02 wt. % to about 0.5 wt. %, or from about 0.03 wt. % to about 0.3 wt. %).

The disclosed polishing compositions are generally acidic, having a pH of less than 7 (e.g., less than about 5). For example, the pH may be greater than about 1 (e.g., greater than about 1.5 or greater than about 2, or greater than about 2.5). The pH may be less than about 6 (e.g., less than about 5, less than about 4, or less than about 3). Accordingly, it will be understood that the pH of the polishing composition may be bounded by any of the aforementioned endpoints, for example, in a range from about 1 to about 6 (e.g., from about 1 to about 5, from about 2 to about 5, or from about 2 to about 4). In part to minimize safety and shipping concerns, the pH is preferably greater than about 2.

The pH of the polishing composition may be achieved and/or maintained by any suitable means. The polishing composition may include substantially any suitable pH adjusting agents or buffering systems. For example, suitable pH adjusting agents may include nitric acid, sulfuric acid, phosphoric acid, phthalic acid, citric acid, adipic acid, oxalic acid, malonic acid, maleic acid, ammonium hydroxide, and the like while suitable buffering agents may include phosphates, sulfates, acetates, malonates, oxalates, borates, ammonium salts, and the like.

The disclosed compositions further include an iron-containing tungsten polishing accelerator and a corresponding stabilizer. An iron-containing accelerator as used herein is an iron-containing chemical compound that increases the removal rate of tungsten during a tungsten CMP operation. For example, the iron-containing accelerator may include a soluble iron-containing catalyst such as is disclosed in U.S. Pat. Nos. 5,958,288 and 5,980,775. Such an iron-containing catalyst may be soluble in the liquid carrier and may include, for example, ferric (iron III) or ferrous (iron II) compounds such as iron nitrate, iron sulfate, iron halides, including fluorides, chlorides, bromides, and iodides, as well as perchlorates, perbromates and periodates, and organic iron compounds such as iron acetates, carboxylic acids, acetylacetonates, citrates, gluconates, malonates, oxalates, phthalates, and succinates, and mixtures thereof.

An iron-containing accelerator may also include an iron-containing activator (e.g., a free radical producing compound) or an iron-containing catalyst associated with (e.g., coated or bonded to) the surface of the colloidal silica particle such as is disclosed in U.S. Pat. Nos. 7,029,508 and 7,077,880. For example, the iron-containing accelerator may be bonded with the silanol groups on the surface of the colloidal surface particles.

The amount of iron-containing accelerator in the polishing composition may be varied depending upon the oxidizing agent used and the chemical form of the accelerator. When the oxidizing agent (described in more detail below) is hydrogen peroxide (or one of its analogs) and a soluble iron-containing catalyst is used (such as ferric nitrate or hydrates of ferric nitrate), the catalyst may be present in the composition at point of use in an amount sufficient to provide a range from about 0.5 to about 3000 ppm Fe based on the total weight of the composition. The polishing composition may include about 1 ppm Fe or more at point of use (e.g., about 2 ppm or more, about 5 ppm or more, or about 10 ppm or more). The polishing composition may include about 1000 ppm Fe or less at point of use (e.g., about 500 ppm or less, about 200 ppm or less, or about 100 ppm or less). Accordingly, the polishing composition may include Fe in a range bounded by any one of the above endpoints. The composition may include from about 1 to about 1000 ppm Fe at point of use (e.g., from about 2 to about 500 ppm, from about 5 to about 200 ppm, or from about 10 to about 100 ppm).

Embodiments of the polishing composition including an iron-containing accelerator may further include a stabilizer. Without such a stabilizer, the iron-containing accelerator and the oxidizing agent, if present, may react in a manner that degrades the oxidizing agent rapidly over time. The addition of a stabilizer tends to reduce the effectiveness of the iron-containing accelerator such that the choice of the type and amount of stabilizer added to the polishing composition may have a significant impact on CMP performance. The addition of a stabilizer may lead to the formation of a stabilizer/accelerator complex that inhibits the accelerator from reacting with the oxidizing agent, if present, while at the same time allowing the accelerator to remain sufficiently active so as to promote rapid tungsten polishing rates.

Useful stabilizers include phosphoric acid, organic acids, phosphonate compounds, nitriles, and other ligands which bind to the metal and reduce its reactivity toward hydrogen peroxide decomposition and mixture thereof. The acid stabilizers may be used in their conjugate form, e.g., the carboxylate can be used instead of the carboxylic acid. The term “acid” as it is used herein to describe useful stabilizers also means the conjugate base of the acid stabilizer. Stabilizers can be used alone or in combination and significantly reduce the rate at which oxidizing agents such as hydrogen peroxide decompose.

Preferred stabilizers include phosphoric acid, acetic acid, phthalic acid, citric acid, adipic acid, oxalic acid, malonic acid, succinic acid, glutaric acid, pimelic acid, suberic acid, azelaic acid, sebacic acid, maleic acid, glutaconic acid, muconic acid, ethylenediaminetetraacetic acid (EDTA), propylenediaminetetraacetic acid (PDTA), and mixtures thereof. The preferred stabilizers may be added to the compositions of this invention in an amount ranging from about 1 equivalent per iron-containing accelerator to about 3.0 weight percent or more (e.g., from about 3 to about 10 equivalents). As used herein, the term “equivalent per iron-containing accelerator” means one molecule of stabilizer per iron ion in the composition. For example, 2 equivalents per iron-containing accelerator means two molecules of stabilizer for each catalyst ion.

The polishing composition may optionally further include an oxidizing agent. The oxidizing agent may be added to the polishing composition during the slurry manufacturing process or just prior to the CMP operation (e.g., in a tank or slurry distribution system located at the semiconductor fabrication facility as in common in the industry). Preferable oxidizing agents include inorganic or organic per-compounds. A per-compound as defined herein is a compound containing at least one peroxy group (—O—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-t-butyl peroxide, monopersulfates (SO₅⁼), dipersulfates (S₂O₈⁼), and sodium peroxide. Examples of compounds containing an element in its highest oxidation state include but are not limited to periodic acid, periodate salts, perbromic acid, perbromate salts, perchloric acid, perchlorate salts, perboric acid, and perborate salts and permanganates. The most preferred oxidizing agent is hydrogen peroxide.

The oxidizing agent may be present in the polishing composition in an amount ranging, for example, from about 0.1 to about 20 wt. % at point of use. For example, in embodiments in which a hydrogen peroxide oxidizer and a soluble iron-containing accelerator are used, the oxidizer may be present in the polishing composition in an amount ranging from about 0.1 wt. % to about 10 wt. % at point of use (e.g., from about 0.5 wt. % to about 5 wt. % or from about 1 wt. % to about 5 wt. %).

The disclosed polishing composition further includes at least one compound that inhibits (or further inhibits) tungsten etching. Suitable inhibitor compounds are intended to inhibit the conversion of solid tungsten into soluble tungsten compounds while at the same time allowing for effective removal of solid tungsten via the CMP operation. The polishing composition may include substantially any suitable inhibitor, for example, inhibitor compounds disclosed in commonly assigned U.S. Pat. Nos. 9,238,754; 9,303,188; and 9,303,189.

Example classes of compounds that that are useful inhibitors of metal tungsten etching include compounds having nitrogen containing functional groups such as nitrogen containing heteroycles, alkyl ammonium ions, amino alkyls, and amino acids. Useful amino alkyl corrosion inhibitors include, for example, hexylamine, tetramethyl-p-phenylene diamine, octylamine, diethylene triamine, dibutyl benzylamine, aminopropylsilanol, aminopropylsiloxane, dodecylamine, mixtures thereof, and synthetic and naturally occurring amino acids including, for example, lysine, aspartic acid, tyrosine, glutamine, glutamic acid, cystine, glycine (aminoacetic acid), histidine, and arginine.

The inhibitor compound may alternatively and/or additionally include an amine compound in solution in the liquid carrier. The amine compound (or compounds) may include a primary amine, a secondary amine, a tertiary amine, or a quaternary amine. The amine compound may further include a monoamine, a diamine, a triamine, a tetramine, or an amine-based polymer having a large number of repeating amine groups (e.g., 4 or more amine groups).

In certain embodiments, the tungsten etch inhibitor may include a polyamino acid compound. Suitable polyamino acid compounds may include substantially any suitable amino acid monomer groups, for example, including polyarginine, polyhistidine, polyalanine, polyglycine, polytyrosine, polyproline, polyornithine and polylysine. In certain embodiments, polylysine is a preferred polyamino acid. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. In certain embodiments, the polylysine may be primarily ε-poly-L-lysine.

The tungsten etch inhibitor may also (or alternatively) include a derivatized polyamino acid (i.e., a cationic polymer containing a derivatized amino acid monomer unit). For example, the derivatized polyamino acid may include derivatized polyarginine, derivatized polyornithine, derivatized polyhistidine, and derivatized polylysine. CMP compositions including derivatized polyamino acid compounds are disclosed in U.S. Patent Publication 2021/0206920.

In certain advantageous embodiments, the disclosed polishing compositions include an amino acid tungsten etch inhibitor such as glycine, glutamic acid, lysine, histidine, arginine, aspartic acid, or a mixture thereof or a polyamino acid tungsten etch inhibitor such as polyhistidine, polylysine, polyarginine, or a mixture thereof. It will, of course, be understood that the tungsten etch inhibitor may be used in any accessible form (e.g., the conjugate acid or base and salt forms may be used instead of or in addition to the acid form). The term “acid” as it is used in this context to describe useful compounds is intended to mean the acid and any form that can be accessed by adjusting the pH to modify any titratable functional groups that may be present. Such forms include its conjugate base or acid and any other salt there-of. For example, the term “glutamic acid” means the amino acid form as well as the conjugate acid formed by protonating the amine functional group. Likewise, “polylysine” means the polylysine polyamino acid as well as its conjugate acid formed by protonating the amine functional group.

The disclosed polishing compositions may include substantially any suitable concentration of the tungsten etch inhibitor compound. In general, the concentration is desirably high enough to provide adequate etch inhibition at a range of oxidizer (e.g., hydrogen peroxide) concentrations, but low enough so that the compound is soluble and does not reduce tungsten polishing rates below acceptable levels. By soluble it is meant that the compound is fully dissolved in the liquid carrier or that it forms micelles in the liquid carrier or is carried in micelles.

The amount of tungsten etch inhibitor generally depends on the type of inhibitor used as well as on the oxidizing agent used and its concentration and the chemical form of the iron containing accelerator and its concentration. In certain desirable embodiments, the concentration of the tungsten etch inhibitor may be about 10 μM or more at point of use (e.g., about 0.1 mM or more, about 0.2 mM or more, about 0.3 mM or more, about 0.5 mM or more, or about 1 mM or more). The concentration of the tungsten etch inhibitor may be 50 mM or less at point of use (e.g., 40 mM or less, 30 mM or less, 20 mM or less, 15 mM or less, or 10 mM or less). Accordingly, the concentration of the tungsten etch inhibitor may be in a range bounded by any of the aforementioned endpoints. For example, the inhibitor concentration may be in a range from about 0.1 mM to about 50 mM at point of use (e.g., from about 0.3 mM to about 30 mM, from about 0.5 mM to about 20 mM, or from about 1 mM to about 10 mM).

In polishing compositions that include a polyamino acid tungsten etch inhibitor (such as polylysine), the polishing composition may include, for example, from about 1 ppm to about 100 ppm by weight of the polyamino acid tungsten etch inhibitor at point of use (e.g., from about 2 ppm to about 50 ppm or from about 3 ppm to about 30 ppm). In polishing compositions that include an amino acid tungsten etch inhibitor (such as glutamic acid), the polishing composition may include, for example, from about 50 ppm to about 5000 ppm by weight (0.05 wt. %) of the amino acid tungsten etch inhibitor at point of use (e.g., from about 100 ppm to about 2500 ppm or from about 150 ppm to about 1500 ppm).

The disclosed embodiments further include a sulfur containing anionic surfactant. By anionic surfactant it is meant that the compound includes a functional group that carries a negative charge in a desired pH range (e.g., at the pH of the composition). By sulfur containing it is meant that the anionic surfactant includes at least one sulfur atom, for example, with preferred embodiments including a sulfate or sulfonate functional group. In example embodiments, the sulfur containing anionic surfactant may be described by one of the following formulas: (i) RSO₃⁻ and (ii) ROSO₃⁻ where R represents an alkyl or alkane group, a branched alkyl or alkane group, or a cyclic group having less than 14 carbon atoms. In preferred embodiments, R represents an alkyl or alkane group or branched alkyl or alkane group in which the longest straight carbon chain includes from about 4 carbon atoms to about 12 carbon atoms, and more preferably from about 6 carbon atoms to about 10 carbon atoms.

Example sulfur containing anionic surfactants may include butane sulfonate, butyl sulfate, pentane sulfonate, pentyl sulfate, hexane sulfonate, hexyl sulfate, butyl ethyl sulfonate, butyl ethyl sulfate, heptane sulfonate, heptyl sulfate, octane sulfonate, octyl sulfate, decane sulfonate, decyl sulfate, dodecane sulfonate, dodecyl sulfate, ethyl 2-hexyl sulfonate, ethyl 2-hexane sulfate and mixtures thereof. It will of course be understood that where applicable the above-described anionic surfactants may be provided as the parent acids, or as conjugate base salts or mixtures thereof, including any reasonable positively charged counterions, such as sodium, potassium, or ammonium cations.

The polishing composition may include substantially any suitable amount of the sulfur containing anionic surfactant at point of use. For example, the polishing composition may include 1 ppm by weight or more of the sulfur containing anionic surfactant at point of use (e.g., about 10 ppm by weight or more, about 20 ppm by weight or more, about 30 ppm by weight or more, or about 50 ppm by weight or more). The amount of anionic surfactant in the composition may be 2,000 ppm by weight or less at point of use (e.g., about 1000 ppm by weight or less, about 500 ppm by weight or less, about 300 ppm by weight or less, or about 200 ppm by weight or less). Accordingly, it will be understood that the amount of anionic surfactant may be in a range bounded by any two of the aforementioned endpoints, for example, in a range from about 1 ppm by weight to about 2,000 ppm by weight at point of use (e.g., from about 10 ppm by weight to about 1000 ppm by weight, from about 20 ppm by weight to about 500 ppm by weight, from about 30 ppm by weight to about 300 ppm by weight, or from about 50 ppm by weight to about 200 ppm by weight).

Disclosed polishing compositions may include substantially any additional optional chemical additives. For example, the disclosed compositions may include additional tungsten etch inhibitors and topography control agents, dispersants, and biocides. Such additional additives are purely optional. The disclosed embodiments are not so limited and do not require the use of any one or more of such additives. In embodiments further including a biocide, the biocide may include any suitable biocide, for example an isothiazolinone biocide known to those of ordinary skill in the art.

The polishing composition may be prepared using any suitable techniques, many of which are known to those skilled in the art. The polishing composition may be prepared in a batch or continuous process. Generally, the polishing composition may be prepared by combining the components thereof in any order. The term “component” as used herein includes the individual ingredients (e.g., the colloidal silica, the iron-containing accelerator, the amine compound, etc.).

For example, the polishing composition components (such as the iron-containing accelerator, the stabilizer, the tungsten etch inhibitor, and/or the biocide) may be added directly to a silica dispersion (such as an anionic or cationic colloidal silica). The silica dispersion and the other components may be blended together using any suitable techniques for achieving adequate mixing. Such blending/mixing techniques are well known to those of ordinary skill in the art. The oxidizing agent, when present, may be added at any time during the preparation of the polishing composition. For example, the polishing composition may be prepared prior to use, with one or more components, such as the oxidizing agent, being added just prior to the CMP operation (e.g., within about 1 minute, or within about 10 minutes, or within about 1 hour, or within about 1 day, or within about 1 week of the CMP operation). The polishing composition also may also be prepared by mixing the components at the surface of the substrate (e.g., on the polishing pad) during the CMP operation.

The polishing composition may advantageously be supplied as a one-package system comprising a colloidal silica having the above-described physical properties and other optional components. An oxidizing agent may be desirably supplied separately from the other components of the polishing composition and may be combined, e.g., by the end-user, with the other components of the polishing composition shortly before use (e.g., 1 week or less prior to use, 1 day or less prior to use, 1 hour or less prior to use, 10 minutes or less prior to use, or 1 minute or less prior to use). Various other two-container, or three- or more-container, combinations of the components of the polishing composition are within the knowledge of one of ordinary skill in the art.

The polishing composition of the invention may also be provided as a concentrate which is intended to be diluted with an appropriate amount of water prior to use. In such an embodiment, the polishing composition concentrate may include the abrasive (e.g., silica), the iron-containing accelerator, the stabilizer, the tungsten etch inhibitor, and an optional biocide in amounts such that, upon dilution of the concentrate with an appropriate amount of water, and an optional oxidizing agent if not already present in an appropriate amount, each component of the polishing composition will be present in the polishing composition in an amount within the appropriate ranges recited above for each component. For example, the colloidal silica and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively), along with the oxidizing agent in a suitable amount, each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be advantageously used to polish a substrate including a tungsten layer and a dielectric material such as silicon oxide. In such applications, the tungsten layer may be deposited over one or more barrier layers, for example, including titanium and/or titanium nitride (TiN). The dielectric layer may be a metal oxide such as a silicon oxide layer derived from tetraethylorthosilicate (TEOS), porous metal oxide, porous or non-porous carbon doped silicon oxide, fluorine-doped silicon oxide, glass, organic polymer, fluorinated organic polymer, or any other suitable high or low-k insulating layer.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as tungsten, titanium, titanium nitride, and/or a dielectric material as described herein) to polish the substrate.

In certain desirably embodiments, the disclosed polishing composition enables improved planarity with minimal or no loss in throughput. Example polishing compositions provide high tungsten and barrier removal rates and rapid wafer clear times. Moreover, the disclosed polishing compositions may provide for low erosion and dishing with reduced patterned wafer oxide loss.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

It will be understood that the disclosure includes numerous embodiments. These embodiments include, but are not limited to, the following embodiments.

In a first embodiment a chemical mechanical polishing composition may comprise, consist of, or consist essentially of a liquid carrier; cationic abrasive particles dispersed in the liquid carrier; an iron-containing accelerator; a tungsten etch inhibitor; a sulfur containing anionic surfactant; and a pH of less than about 5.

A second embodiment may include the first embodiment, wherein the cationic abrasive particles comprise colloidal silica.

A third embodiment may include the second embodiment, wherein the colloidal silica particles include an internal aminosilane compound or an aminosilane compound bonded to an external surface of the particle.

A fourth embodiment may include any one of the second through third embodiments, wherein the colloidal silica has a zeta potential of greater than about 20 mV.

A fifth embodiment may include any one of the second through fourth embodiments, comprising less than about 1 weight percent of the colloidal silica particles at point of use.

A sixth embodiment may include any one of the first through fifth embodiments, wherein the iron-containing accelerator comprises a soluble iron-containing catalyst and the composition further comprises a stabilizer bound to the soluble iron-containing catalyst, the stabilizer being selected from the group consisting of phosphoric acid, phthalic acid, citric acid, adipic acid, oxalic acid, malonic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, and mixtures thereof.

A seventh embodiment may include any one of the first through sixth embodiments, wherein the tungsten etch inhibitor is positively charged at the pH of the composition.

An eighth embodiment may include any one of the first through seventh embodiments, wherein the tungsten etch inhibitor comprises an amino acid selected from the group consisting of glycine, glutamic acid, arginine, aspartic acid, lysine, histidine, and mixtures thereof or a polyamino acid selected from the group consisting of polylysine, polyarginine, polyhistidine, and mixtures thereof.

A ninth embodiment may include any one of the first through eighth embodiments, wherein the sulfur containing anionic surfactant has the formula (i) RSO₃⁻ or (ii) ROSO₃⁻ wherein R represents an alkyl group, a branched alkyl group, or a cyclic group having less than 14 carbon atoms.

A tenth embodiment may include the ninth embodiment, wherein R represents an alkyl group or a branched alkyl group having a longest straight carbon chain including from about 4 carbon atoms to about 12 carbon atoms.

An eleventh embodiment may include the tenth embodiment, wherein the longest straight carbon chain includes from about 6 carbon atoms to about 10 carbon atoms.

A twelfth embodiment may include any one of the first through eleventh embodiments, wherein the sulfur containing anionic surfactant is selected from the group consisting of butane sulfonate, butyl sulfate, pentyl sulfonate, pentyl sulfate, hexane sulfonate, hexyl sulfate, butyl ethyl sulfonate, butyl ethyl sulfate, octane sulfonate, octyl sulfate, decane sulfonate, decyl sulfate, dodecane sulfonate, dodecyl sulfate, ethyl 2-hexyl sulfonate, ethyl 2-hexane sulfate and mixtures thereof.

A thirteenth embodiment may include any one of the first through twelfth embodiments, wherein the sulfur containing anionic surfactant is selected from the group consisting of hexane sulfonate, hexyl sulfate, butyl ethyl sulfonate, butyl ethyl sulfate, octane sulfonate, octyl sulfate, decane sulfonate, decyl sulfate, ethyl 2-hexyl sulfonate, ethyl 2-hexane sulfate and mixtures thereof.

A fourteenth embodiment may include any one of the first through thirteenth embodiments, comprising from about 10 ppm by weight to about 1000 ppm by weight of the sulfur containing anionic surfactant at point of use.

A fifteenth embodiment may include any one of the first through fourteenth embodiments, wherein the tungsten etch inhibitor comprises from about 1 ppm by weight to about 100 ppm by weight of polylysine at point of use.

A sixteenth embodiment may include any one of the first through fourteenth embodiments, wherein the tungsten etch inhibitor comprises from about 50 ppm by weight to about 5000 ppm by weight of glutamic acid, glycine, lysine, or a mixture thereof at point of use.

A seventeenth embodiment may include any one of the first through sixteenth embodiments, having a pH in a range from about 2 to about 4.

An eighteenth embodiment may include any one of the first through seventeenth embodiments, further comprising a hydrogen peroxide oxidizer.

A nineteenth embodiment may include any one of the first through eighteenth embodiments, wherein: the sulfur containing anionic surfactant is selected from the group consisting of butane sulfonate, butyl sulfate, pentyl sulfonate, pentyl sulfate, hexane sulfonate, hexyl sulfate, butyl ethyl sulfonate, butyl ethyl sulfate, octane sulfonate, octyl sulfate, decane sulfonate, decyl sulfate, dodecane sulfonate, dodecyl sulfate, ethyl 2-hexyl sulfonate, ethyl 2-hexane sulfate and mixtures thereof; the composition includes from about 10 ppm by weight to about 1000 ppm by weight of the sulfur containing anionic surfactant; and the tungsten etch inhibitor comprises from about 1 ppm by weight to about 100 ppm by weight of polylysine at point of use or from about 50 ppm by weight to about 5000 ppm by weight of glutamic acid, glycine, lysine, or a mixture thereof at point of use.

In a twentieth embodiment a method of chemical mechanical polishing a patterned tungsten containing substrate may include: (a) contacting the substrate with any one of the polishing compositions recited in the first through the nineteenth embodiments, (b) moving the polishing composition relative to the substrate; and (c) abrading the substrate to remove a portion of at least one tungsten layer from the substrate and thereby polish the substrate.

The following examples further illustrate the invention but, of course, should not be construed as in any way limiting its scope.

### Example 1

Five tungsten polishing compositions (compositions 1A-1E) were prepared and evaluated. Each composition included 0.1 weight percent (1000 ppm by weight) colloidal silica having an average particle size of about 120 nm and including a permanent positive charge imparted by surface treatment with an aminosilane as described in Example 7 of U.S. Pat. No. 9,382,450. Each composition further included 200 ppm by weight ferric nitrate nonahydrate (27 ppm Fe), 300 ppm by weight malonic acid, 2 ppm by weight Kathon LX biocide, and 1 weight percent hydrogen peroxide. The pH of each composition was adjusted to 2.7 using potassium hydroxide. Polishing composition 1A further included 10 ppm by weight ε-poly-L-lysine. Polishing composition 1B further included 10 ppm by weight ε-poly-L-lysine and 10 ppm by weight Starquat DCE 12,14-HG (StarChem LLC). Polishing composition 1C further included 500 ppm by weight L-glutamic acid. Polishing compositions 1D and 1E further included 500 ppm by weight L-glutamic acid and 100 ppm by weight ethyl hexyl sodium sulfate (1D) or 100 ppm arginine (1E). Polishing compositions 1A-1E are further summarized in Table 1A.

TABLE 1A

| Polishing | | |
|---|---|---|
| Composition | Tungsten Etch Inhibitor | Supplemental Additive |
| 1A | 10 ppm | None |
| | ε-poly-L-lysine | |
| 1B | 10 ppm | 10 ppm |
| | ε-poly-L-lysine | StarQuat DCE 12,14-HG |
| 1C | 500 ppm | None |
| | L-glutamic acid | |
| 1D | 500 ppm | 100 ppm ethyl hexyl |
| | L-glutamic acid | sodium sulfate |
| 1E | 500 ppm | 100 ppm arginine |
| | L-glutamic acid | |

Blanket and patterned wafer polishing performance was evaluated by polishing 300 mm blanket wafers having a W layer and Silyb 2 kÅ MIT 754 tungsten patterned wafers (available from Silyb Wafer Services) on a Reflexion® CMP tool (available from Applied Materials) using Pad 5C from commonly assigned U.S. Patent Publication 2021/0008687. The polishing process included a platen speed of 80 rpm, a head speed of 89 rpm, and a slurry flow rate of 100 mL/min. The downforce was 2.5 psi until the barrier film(s) were removed (endpoint) and then reduced to 1.2 psi for a 25 second over-polish. A 3M A122 conditioning disk was used to apply ex-situ pad conditioning for 24 seconds at 6 pound down force.

The blanket and patterned wafer polishing performance is summarized in Table 1B.

TABLE 1B

| Polishing | W RR | Erosion (Å) | Dishing | Patterned Oxide |
|---|---|---|---|---|
| Composition | (Å/min) | (1 × 1) | (Å) | Loss (Å) |
| 1A | 1379 | 133 | 31 | |
| 1B | 1565 | 284 | 28 | |
| 1C | 1540 | 157 | 92 | 23 |
| 1D | 1424 | 153 | 48 | 14 |
| 1E | 1275 | 267 | 60 | |

As is apparent from the results set forth in Table 1B, polishing compositions 1B and 1E (including the Starquat and arginine supplemental additives) exhibited higher erosion than the control compositions (1A and 1D). Polishing composition 1E further exhibited higher dishing. Polishing composition 1D (including the inventive ethyl hexyl sodium sulfate additive) exhibited similar erosion (153 Å vs. 157 Å), reduced dishing (48 Å vs. 92 Å), a similar W removal rate (1424 Å/min vs. 1540 Å/min), and reduced patterned oxide loss (14 Å vs. 23 Å) as compared to the control (1C). It is therefore evident that the polishing composition including the inventive sulfur containing anionic surfactant (ethyl hexyl sodium sulfate in this example) exhibited improved overall planarity.

### Example 2

Three tungsten polishing compositions (compositions 2A-2C) were prepared and evaluated. Each composition included 0.2 weight percent (2000 ppm by weight) of the colloidal silica described above in Example 1. Each composition further included 200 ppm by weight ferric nitrate nonahydrate (27 ppm Fe), 400 ppm by weight malonic acid, 10 ppm by weight ε-poly-L-lysine, 2 ppm by weight Kathon LX biocide, and 3 weight percent hydrogen peroxide. The pH of each composition was adjusted to 2.7 using potassium hydroxide. Polishing composition 2B further included 100 ppm by weight ethyl hexyl sodium sulfate. Polishing composition 2C further included 100 ppm by weight L-cysteic acid monohydrate. Polishing compositions 2A-2C are further summarized in Table 2A.

TABLE 2A

| Polishing | | |
|---|---|---|
| Composition | Tungsten Etch Inhibitor | Supplemental Additive |
| 2A | 10 ppm | None |
| | ε-poly-L-lysine | |
| 2B | 10 ppm | 100 ppm ethyl hexyl |
| | ε-poly-L-lysine | sodium sulfate |
| 2C | 10 ppm | 100 ppm L-cysteic acid |
| | ε-poly-L-lysine | monohydrate |

The patterned wafer polishing performance was evaluated by polishing Silyb 2 kÅ MIT 754 tungsten patterned wafers (available from Silyb Wafer Services) on a Reflexion® CMP tool (available from Applied Materials) with an E6088 polishing pad (available from CMC Materials). The polishing process included a platen speed of 80 rpm, a head speed of 89 rpm, a 3.5 psi downforce, and a slurry flow rate of 100 mL/min using. The wafers were polished to endpoint followed by 15 second over-polish. The endpoint time (time to clear tungsten and barrier films) and the flag time (time to clear tungsten film) were noted. A 3M A122 conditioning disk was used to apply ex-situ pad conditioning for 24 seconds at 6 pound down force.

The patterned wafer polishing performance is summarized in Table 2B.

TABLE 2B

| | | | Patterned | | |
|---|---|---|---|---|---|
| Polishing | Erosion | Dishing | Oxide | Endpoint | Flag Time |
| Composition | (Å) (1 × 1) | (Å) | Loss (Å) | Time (sec) | (sec) |
| 2A | 390 | 29 | 63 | 47 | 38 |
| 2B | 348 | 29 | 51 | 49 | 39 |
| 2C | 353 | 34 | 79 | 63 | 39 |

As is apparent from the results set forth in Table 2B, polishing compositions 2B and 2C (including the ethyl hexyl sodium sulfate and L-cysteic acid monohydrate supplemental additives) exhibited lower erosion and similar dishing to the control composition (2A). Polishing composition 2B (including the ethyl hexyl sodium sulfate) further exhibited a reduced patterned oxide loss (51 Å vs. 63 Å). It is therefore evident that the polishing composition including the inventive sulfur containing anionic surfactant (ethyl hexyl sodium sulfate in this example) exhibited improved overall planarity. Moreover, polishing composition 2B further exhibited similar endpoint and flag times as compared with the control composition 2A indicating that the improved overall planarity can be achieved without a loss of throughput. In contrast, polishing composition 2C (including the L-cysteic acid monohydrate supplemental additive) exhibited increased patterned oxide loss (79 Å vs. 63 Å) and a significantly increased endpoint time (indicating a slower barrier polishing rate) than the control.

### Example 3

Three tungsten polishing compositions (compositions 3A-3C) were prepared and evaluated. Each composition included 0.2 weight percent (2000 ppm by weight) of the colloidal silica described above in Example 1. Each composition further included 200 ppm by weight ferric nitrate nonahydrate (27 ppm Fe), 400 ppm by weight malonic acid, 10 ppm by weight ε-poly-L-lysine, 2 ppm by weight Kathon LX biocide, and 3 weight percent hydrogen peroxide. The pH of each composition was adjusted to 2.7 using potassium hydroxide. Polishing composition 3B further included 100 ppm by weight ethyl hexyl sodium sulfate. Polishing composition 3C further included 100 ppm by weight sodium decylsulfate. Polishing compositions 3A-3C are further summarized in Table 2A.

TABLE 3A

| Polishing | | |
|---|---|---|
| Composition | Tungsten Etch Inhibitor | Supplemental Additive |
| 3A | 10 ppm | None |
| | ε-poly-L-lysine | |
| 3B | 10 ppm | 100 ppm ethyl hexyl |
| | ε-poly-L-lysine | sodium sulfate |
| 3C | 10 ppm | 100 ppm sodium |
| | ε-poly-L-lysine | decylsulfate |

The patterned wafer polishing performance was evaluated by polishing Silyb 2 kÅ MIT 754 tungsten patterned wafers (available from Silyb Wafer Services) on a Mirra® CMP tool (available from Applied Materials) with an E6088 polishing pad (available from CMC Materials). The polishing process was carried out with a platen speed of 80 rpm, a head speed of 89 rpm, a 3.5 psi downforce, and a slurry flow rate of 50 mL/min using. The wafers were polished to endpoint and a 15 second over-polish. A 3M A122 conditioning disk was used to apply ex-situ pad conditioning for 24 seconds at 6 pound down force. TEOS blanket wafers were polished for 60 seconds.

The patterned wafer polishing performance is summarized in Table 2B.

TABLE 3B

| Polishing | Erosion (Å) | Pattern W | Pattern TEOS | Blanket TEOS |
|---|---|---|---|---|
| Composition | (1 × 1) | RR (Å/min) | RR (Å/min) | RR (Å/min) |
| 3A | 351 | 3175 | 483 | 15 |
| 3B | 280 | 3092 | 462 | 18 |
| 3C | 268 | 3024 | 425 | 18 |

As is apparent from the results set forth in Table 3B, polishing compositions 3B and 3C (including the ethyl hexyl sulfate and decylsulfate supplemental additives) exhibited lower erosion than the control composition (2A). Polishing compositions 3B and 3C further exhibited similar (or slightly reduced) patterned tungsten removal rates and reduced patterned oxide (TEOS) removal rates (indicative of reduced patterned oxide loss). It is therefore evident that the polishing composition including the inventive sulfur containing anionic surfactant (ethyl hexyl sulfate and sodium decylsulfate in this example) exhibited improved overall planarity and comparable through put with the control composition (3A).

### Example 4

The colloidal stability of fifteen (seventeen if 12C) tungsten polishing compositions (compositions 4A-4N) was evaluated. Each composition included 0.11 weight percent (1100 ppm by weight) of the colloidal silica described above in Example 1. Each composition further included 100 ppm by weight ferric nitrate nonahydrate (14 ppm Fe), 300 ppm by weight malonic acid, 400 ppm by weight L-glutamic acid, and 15 ppm by weight Kathon LX biocide. The pH of each composition was adjusted to 2.5. Each composition further included a sulfur containing anionic surfactant in the amount (in ppm by weight) listed in Table 4A. The carbon chain length of each anionic surfactant is also listed in Table 4A

TABLE 4A

| Polishing | | Carbon Chain |
|---|---|---|
| Composition | Sulfur Containing Anionic Surfactant | Length |
| 4A | None | |
| 4B | 100 ppm 1-Propane Sulfonic Acid | 3 |
| 4C | 1000 ppm 1-Propane Sulfonic Acid | 3 |
| 4D | 100 ppm Sodium Butylsulfate | 4 |
| 4E | 1000 ppm Sodium Butylsulfate | 4 |
| 4F | 100 ppm Sodium Hexane Sulfonate | 6 |
| 4G | 1000 ppm Sodium Hexane Sulfonate | 6 |
| 4H | 100 ppm Octane Sulfonic Acid Na Salt | 8 |
| 4I | 1000 ppm Octane Sulfonic Acid Na Salt | 8 |
| 4J | 100 ppm Sodium Decylsulfate | 10 |
| 4K | 1000 ppm Sodium Decylsulfate | 10 |
| 4L | 100 ppm 1-Tetradecanesulfonic Acid | 14 |
| 4M | 100 Ammonium Lauryl Sulfate | 14 |
| 4N | 1-Hexadecanesulfonic Acid | 16 |

The average particle size and zeta potential of the colloidal silica were measured for each of the polishing compositions using a Zetasizer available from Malvern. The test results are shown in FIG. 4B.

TABLE 4B

| Polishing | Particle | Zeta Potential |
|---|---|---|
| Composition | Size (nm) | (mV) |
| 4A | 121 | 48.9 |
| 4B | 123 | 47.7 |
| 4C | 121 | 45.5 |
| 4D | 120 | 52 |
| 4E | 122 | 43.3 |
| 4F | 120 | 48.5 |
| 4G | 124 | 44.6 |
| 4H | 124 | 49 |
| 4I | 128 | 44.5 |
| 4J | 125 | 46 |
| 4K | 125 | 48.2 |
| 4L | 3116 | 48.6 |
| 4M | 2852 | 19 |
| 4N | Gelled | Gelled |

As is apparent from the results set forth in Table 4B, polishing compositions 4A-4K (including the sulfur containing anionic surfactants having a carbon chain length of 12 or less) were colloidally stable exhibiting particles sizes and zeta potentials similar to the control composition (4A). The polishing compositions 4L-4M (including the sulfur containing anionic surfactants having a carbon chain length of 14 or more) were colloidally unstable.

### Example 5

The colloidal stability of twenty-one tungsten polishing compositions (compositions 5AA-5GC) was evaluated. Each composition included 1.1 weight percent (11000 ppm by weight) of one of three types of colloidal silica having a permanent positive charge. Type A colloidal silica had an average particle size of about 100 nm and included a permanent positive charge imparted by surface treatment with an aminosilane as described in Example 7 of U.S. Pat. No. 9,382,450. Type B colloidal silica had an average particle size of about 50 nm and included an internal aminosilane as described Example 13 of U.S. Pat. No. 9,422,456. Type C colloidal silica had an average particle size of about 120 nm and included a permanent positive charge imparted by surface treatment with an aminosilane as described in Example 7 of U.S. Pat. No. 9,382,450.

Each composition further included 100 ppm by weight ferric nitrate nonahydrate (14 ppm Fe), 300 ppm by weight malonic acid, 400 ppm by weight L-glutamic acid, and 15 ppm by weight Kathon LX biocide. The pH of each composition was adjusted to 2.5. Each composition further included 100 ppm by weight of the sulfur containing anionic surfactant listed in Table 5A. The carbon chain length of each anionic surfactant is also listed in Table 5A.

TABLE 5A

| | | | Carbon |
|---|---|---|---|
| Polishing | Colloidal | Sulfur Containing | Chain |
| Composition | Silica Type | Anionic Surfactant | Length |
| 5AA | A | None | 0 |
| 5AB | B | None | 0 |
| 5AC | C | None | 0 |
| 5BA | A | Sodium Butylsulfate | 4 |
| 5BB | B | Sodium Butylsulfate | 4 |
| 5BC | C | Sodium Butylsulfate | 4 |
| 5CA | A | Sodium Benzene Sulfonate | 6 |
| 5CB | B | Sodium Benzene Sulfonate | 6 |
| 5CC | C | Sodium Benzene Sulfonate | 6 |
| 5DA | A | Sodium Hexane Sulfonate | 6 |
| 5DB | B | Sodium Hexane Sulfonate | 6 |
| 5DC | C | Sodium Hexane Sulfonate | 6 |
| 5EA | A | 1-Octanesulfonic acid Sodium Salt | 8 |
| 5EB | B | 1-Octanesulfonic acid Sodium Salt | 8 |
| 5EC | C | 1-Octanesulfonic acid Sodium Salt | 8 |
| 5FA | A | Sodium 2-ethylhexyl sulfate purum | 8 |
| 5FB | B | Sodium 2-ethylhexyl sulfate purum | 8 |
| 5FC | C | Sodium 2-ethylhexyl sulfate purum | 8 |
| 5GA | A | Sodium Decylsulfate | 10 |
| 5GB | B | Sodium Decylsulfate | 10 |
| 5GC | C | Sodium Decylsulfate | 10 |

The average particle size and zeta potential of the colloidal silica were measured for each of the polishing compositions using a Zetasizer available from Malvern. The test results are shown in FIG. 5B.

TABLE 5B

| Polishing | Particle Size | Zeta Potential |
|---|---|---|
| Composition | (nm) | (mV) |
| 5AA | 96 | 41.1 |
| 5AB | 54 | 30.6 |
| 5AC | 123 | 35.6 |
| 5BA | 98 | 38.6 |
| 5BB | 58 | 28.6 |
| 5BC | 124 | 34.5 |
| 5CA | 99 | 32.2 |
| 5CB | 54 | 26.8 |
| 5CC | 125 | 28.2 |
| 5DA | 100 | 29.3 |
| 5DB | 54 | 25.8 |
| 5DC | 122 | 24.9 |
| 5EA | 98 | 34.6 |
| 5EB | 53 | 26.3 |
| 5EC | 126 | 23.1 |
| 5FA | 98 | 37.5 |
| 5FB | 53 | 27.8 |
| 5FC | 127 | 32.0 |
| 5GA | 98 | 39.1 |
| 5GB | 53 | 27.7 |
| 5GC | 124 | 34.3 |

As is apparent from the results set forth in Table 5B, polishing compositions 5AA-5GC (including the sulfur containing anionic surfactants having a carbon chain length of 12 or less) were colloidally stable exhibiting particles sizes and zeta potentials similar to the control composition (5AA-5AC) over a range of colloidal silica particles sizes (from about 50 nm to about 120 nm).

### Example 6

The colloidal stability of nine tungsten polishing compositions (compositions 6A-6I) was evaluated. Each composition included 1.1 weight percent of the colloidal silica described above in Example 1. Each composition further included 100 ppm by weight ferric nitrate nonahydrate (14 ppm Fe), 300 ppm by weight malonic acid, 400 ppm by weight L-glutamic acid, and 15 ppm by weight Kathon LX biocide. The pH of each composition was adjusted to 2.5. Each composition further included a sulfur containing anionic surfactant in the amount (in ppm by weight) listed in Table 6A. The carbon chain length of each anionic surfactant is also listed in Table 6A.

TABLE 6A

| Polishing | | Carbon Chain |
|---|---|---|
| Composition | Sulfur Containing Anionic Surfactant | Length |
| 6A | None | — |
| 6B | 100 ppm Sodium Butylsulfate | 4 |
| 6C | 1000 ppm Sodium Butylsulfate | 4 |
| 6D | 100 ppm Sodium Hexane Sulfonate | 6 |
| 6E | 1000 ppm Sodium Hexane Sulfonate | 6 |
| 6F | 100 ppm Octane Sulfonic Acid Na Salt | 8 |
| 6G | 1000 ppm Octane Sulfonic Acid Na Salt | 8 |
| 6H | 100 ppm Sodium Decylsulfate | 10 |
| 6I | 1000 ppm Sodium Decylsulfate | 10 |

The average particle size and zeta potential of the colloidal silica were measured for each of the polishing compositions using a Zetasizer available from Malvern. The test results are listed in Table 6B.

TABLE 6B

| Polishing | Particle Size | Zeta Potential |
|---|---|---|
| Composition | (nm) | (mV) |
| 6A | 120 | 51.6 |
| 6B | 121 | 48.3 |
| 6C | 122 | 42.4 |
| 6D | 123 | 49.2 |
| 6E | 121 | 43.6 |
| 6F | 124 | 48.2 |
| 6G | 121 | 43.7 |
| 6H | 125 | 46.1 |
| 6I | 133 | 40.7 |

As is apparent from the results set forth in Table 6B, polishing compositions 6B-6I (including the sulfur containing anionic surfactants having a carbon chain length in range from 4 to 10) were colloidally stable exhibiting particle sizes and zeta potentials similar to the control composition (6A). The particle size of polishing composition 6I (including 1000 ppm sodium decylsulfate and 1.1 weight percent colloidal silica) increased noticeably from 120 to 133 nm, however, the composition remained colloidally stable.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier;
cationic abrasive particles dispersed in the liquid carrier;
an iron-containing accelerator;
a tungsten etch inhibitor;
a sulfur containing anionic surfactant; and
a pH of less than about 5.

2. The composition of claim 1, wherein the cationic abrasive particles comprise colloidal silica.

3. The composition of claim 2, wherein the colloidal silica particles include an internal aminosilane compound or an aminosilane compound bonded to an external surface of the particle.

4. The composition of claim 2, wherein the colloidal silica has a zeta potential of greater than about 20 mV.

5. The composition of claim 2, comprising less than about 1 weight percent of the colloidal silica particles at point of use.

6. The composition of claim 1, wherein the iron-containing accelerator comprises a soluble iron-containing catalyst and the composition further comprises a stabilizer bound to the soluble iron-containing catalyst, the stabilizer being selected from the group consisting of phosphoric acid, phthalic acid, citric acid, adipic acid, oxalic acid, malonic acid, succinic acid, glutaric acid, pimelic acid, suberic acid, azelaic acid, sebacic acid, maleic acid, glutaconic acid, muconic acid, ethylenediaminetetraacetic acid, propylenediaminetetraacetic acid, and mixtures thereof.

7. The composition of claim 1, wherein the tungsten etch inhibitor is positively charged at the pH of the composition.

8. The composition of claim 1, wherein the tungsten etch inhibitor comprises an amino acid selected from the group consisting of glycine, glutamic acid, arginine, aspartic acid, lysine, histidine, and mixtures thereof or a polyamino acid selected from the group consisting of polylysine, polyarginine, polyhistidine, and mixtures thereof.

9. The composition of claim 1, wherein the sulfur containing anionic surfactant has the formula (i) RSO₃⁻ or (ii) ROSO₃⁻ wherein R represents an alkyl or alkane group, a branched alkyl or alkane group, or a cyclic group having less than 14 carbon atoms.

10. The composition of claim 9, wherein R represents an alkyl or alkane group or a branched alkyl or alkane group having a longest straight carbon chain including from about 4 carbon atoms to about 12 carbon atoms.

11. The composition of claim 10, wherein the longest straight carbon chain includes from about 6 carbon atoms to about 10 carbon atoms.

12. The composition of claim 1, wherein the sulfur containing anionic surfactant is selected from the group consisting of butane sulfonate, butyl sulfate, pentane sulfonate, pentyl sulfate, hexane sulfonate, hexyl sulfate, butyl ethyl sulfonate, butyl ethyl sulfate, octane sulfonate, octyl sulfate, decane sulfonate, decyl sulfate, dodecane sulfonate, dodecyl sulfate, ethyl 2-hexyl sulfonate, ethyl 2-hexane sulfate and mixtures thereof.

13. The composition of claim 1, wherein the sulfur containing anionic surfactant is selected from the group consisting of hexane sulfonate, hexyl sulfate, butyl ethyl sulfonate, butyl ethyl sulfate, octane sulfonate, octyl sulfate, decane sulfonate, decyl sulfate, ethyl 2-hexyl sulfonate, ethyl 2-hexane sulfate and mixtures thereof.

14. The composition of claim 1, comprising from about 10 ppm by weight to about 1000 ppm by weight of the sulfur containing anionic surfactant at point of use.

15. The composition of claim 1, wherein the tungsten etch inhibitor comprises from about 1 ppm by weight to about 100 ppm by weight of polylysine at point of use.

16. The composition of claim 1, wherein the tungsten etch inhibitor comprises from about 50 ppm by weight to about 5000 ppm by weight of glutamic acid, glycine, lysine, or a mixture thereof at point of use.

17. The composition of claim 1 having a pH in a range from about 2 to about 4.

18. The composition of claim 1, further comprising a hydrogen peroxide oxidizer.

19. The composition of claim 1, wherein:
the sulfur containing anionic surfactant is selected from the group consisting of butane sulfonate, butyl sulfate, pentane sulfonate, pentyl sulfate, hexane sulfonate, hexyl sulfate, butyl ethyl sulfonate, butyl ethyl sulfate, octane sulfonate, octyl sulfate, decane sulfonate, decyl sulfate, dodecane sulfonate, dodecyl sulfate, ethyl 2-hexyl sulfonate, ethyl 2-hexane sulfate and mixtures thereof;
the composition includes from about 10 ppm by weight to about 1000 ppm by weight of the sulfur containing anionic surfactant; and
the tungsten etch inhibitor comprises from about 1 ppm by weight to about 100 ppm by weight of polylysine at point of use or from about 50 ppm by weight to about 5000 ppm by weight of glutamic acid, glycine, lysine, or a mixture thereof at point of use.

20. A method of chemical mechanical polishing a patterned tungsten containing substrate, the method comprising:
(a) contacting the substrate with a polishing composition comprising:
a liquid carrier;
cationic abrasive particles dispersed in the liquid carrier;
an iron-containing accelerator;
a tungsten etch inhibitor;
a sulfur containing anionic surfactant; and
a pH of less than about 5;
(b) moving the polishing composition relative to the substrate; and
(c) abrading the substrate to remove a portion of at least one tungsten layer from the substrate and thereby polish the substrate.
